(19) United States
(12) Patent Application Publication
(10) Pub. No.: US 2004/0060728 A1
(43) Pub. Date: Apr. 1, 2004

(54) Method for producing electroconductive structures

(76) Inventors: Philippe Steiert, Greppen (CH); Silke Walz, Sarnen (CH)

Correspondence Address: RANKIN, HILL, PORTER & CLARK, LLP, 700 HUNTINGTON BUILDING, 925 EUCLID AVENUE, SUITE 700, CLEVELAND, OH, 44115-1405, US

(21) Appl. No.: 10/250,496

(22) PCT Filed: Jan. 3, 2002
(86) PCT No.: PCT/CH02/00001

(30) Foreign Application Priority Data
Jan. 4, 2001 (WO) PCT/CH01/00004
Jul. 4, 2001 (CH) 123/01

(51) Int. Cl. H05K 1/00

(52) U.S. Cl. 174/250

(57) ABSTRACT

For the method for manufacturing electrically conducting structures one produces or prepares an electrically insulating layer so that it has a surface with recesses at the locations at which the electrically conducting structures are to arise. At least some of the recesses, perpendicular to a surface of the substrate, have a cross section in which the aspect ratio (the ratio between depth (t) and width (b) of the structures) is between 1:5 and 5:1, for example at least 2:3. The substrate surface is provided with an electrically conducting layer which is thin in comparison to the characteristic dimensions of the recesses. Subsequently the surface of the substrate is galvanised for so long until the recesses are filled.

The invention is concerned with filling recesses in plastics with metal for technical application purposes. Methods for filling recesses in plastics have applications in the field of manufacture of electrical connection elements, e.g. circuit boards, also flexible circuit boards, high-density-interconnects, ball grid array (BGA) substrates, chip scale packages (CSP), multi-chip-module (MCM) substrates, etc. They may however be used for semiconductor components, other elements such as micro-planar coils, micro-relays etc.

The invention especially relates to a method according to the first claim. A connection element and a semi-finished product according to the further independent claims likewise belong to the subject-matter of this patent application.

The constantly advancing miniaturisation in the field of microelectronics also has its effect on the manufacture of electrical connection elements, in particular circuit boards, interconnects, etc. In many fields of application there exists the necessity of replacing the conventional manufacture of circuit boards with new methods step by step. The conventional manufacture of conductor structures is based on the photochemical method and the mechanical drilling of passage holes. Newer set-ups include the drilling of the smallest of holes by way of lasers or by way of plasma etching or by way of the mechanical pressing of perforation tools into circuit board material (microperforation, cf. the international patent publication WO 00/13062 to this).

Whilst the drilling of micro-holes is increasingly carried out with by new methods meeting the up-to-date demands, the structuring of conductive tracks as always is carried out with the tried and trusted methods of photo-structuring. This however involves a multitude of manufacturing steps, including exposure, developing, and the stripping of photoresist. It is thus relatively complicated and also has disadvantages from the environmental point of view.

In contrast to the conventional method, in the U.S. Pat. No. 6,005,198 there is described a method for manufacturing circuit boards, which amongst other things envisages the simultaneous impressing of U-shaped grooves and of cup-shaped recesses by an embossing tool into an insulating and preferably duroplastic substrate. For forming pocket holes out of the cup-shaped recesses for the electrical connection between two conductor layers, material must subsequently further be chemically or mechanically removed away. Thereupon the grooves and the recesses are metallised. This is effected for example in that a conductive paste is pressed into the recesses with a rubber roller. Alternatively to this one may also coat the whole substrate and subsequently introduce insulating material (etchresist) into the recesses with a rubber roller. In an etching process following this the metal layer present in the recesses is protected on account of the etchresist. By way of this method one saves a few processing steps. The method however requires several wet-chemical processes as was previously the case. On account of the relatively wide U-shape of the recesses necessary for this method to function, the miniaturisation furthermore has its limits. Moreover the strip conductors due to design either consist of a relatively poor-conductive, curable paste (“conductive ink”) or they are comparatively thin. For this reason limits are also set to the reliability which may be achieved and to the power which may be transmitted by the strip conductors. The method has not been shown to be so successful in practice since the impressing of the conductor pastes or of the etchresist always entails the smearing of these materials on the remaining surface. The surface however must be absolutely free and clean, which leads to the fact that this must be mechanically ground after the coating process and the curing.

In U.S. Pat. No. 6,035,527 there is disclosed a new type of method for manufacturing circuit boards. In a first step recesses for strip conductors are formed in a substrate. Subsequently a homogeneous precipitation of conducting material is effected, for example by way of the chemical vapour deposition method. The conductor material is subsequently removed again, wherein some conductor material still remains in the recesses which forms strip conductors.

In U.S. Pat. No. 4,651,417 there is described a circuit board manufacturing method in which recesses for strip conductors are mechanically created in a substrate. The substrate is subsequently coated homogeneously with material, for which a vacuum precipitation process, specifically a magnetically enhanced sputtering method is used. The conductor material is finally ground away from the surface of the substrate, wherein conductor material remains in the recesses and forms the strip conductors. If the achieved layer thicknesses are not sufficient, then additionally material may yet be mechanically precipitated.

In U.S. Pat. No. 4,912,844 there is described a method for circuit board manufacture according to which channels for strip conductors are pressed into a substrate and subsequently filled with soldering tin.

The British published patent application 2 212 331 and the Japanese patent application 11 146698 each show a method for manufacturing circuit boards of plastic, where a pattern of recesses is pressed into deformable plastic and subsequently a conductor paste is pressed into the recesses.

All these ideas clearly illustrate the fact that the mechanical creation of strip conductor structures as alternatives to the dominant application of photochemical methods have concerned and stimulated the experts for a long period of time. Despite this none of these methods could assert themselves. The reasons for this amongst others are the following:

Practically all the previously described methods render it necessary to mechanically remove conductor material or conductor material remains from surfaces lying between the strip conductors in one method step. This is however not suitable for very fine strip conductor surfaces. As an alternative, at least one of the above mentioned documents mentions the selective removal of material from the surfaces by way of laser ablation. This as an intensive sequential process is not however economical.

Vacuum precipitation (sputtering, CVC, evaporating) are very slow and cost-intensive processes. The mechanical incorporation of elastic conductor paste (with a doctor blade etc.) has been shown to be only partly suitable for mass production.

With the suggested ideas it is hardly possible to simultaneously manufacture very fine strip conductor structures and strip conductors with a relatively large conductivity. The strip conductors according to the ideas are all either very thin or are limited in specific conductivity (conductor paste . . . )

It is the object of the invention to provide a method for the manufacture of electrically conducting structures with the use of recesses in a substrate. At the same time the method is to render it possible for the structures such as strip conductors and passage holes to have as small as possible lateral dimensions. In comparison to the state of the art however the reliability and the performance of the structures may not be reduced. With strip conductors there thus results the demand that in comparison to existing systems with regard to the surface they should have a lower plane cross-sectional component, i.e. they should have a sufficiently great depth in the substrate. The manufacturing method should be economical and should be able to be realised with apparatus based on present technology.

A method with these properties is made available by the invention, as is defined in the patent claims.

The method is essentially distinguished by the fact that recesses for conductor structures are created and galvanically filled. In a subsequent step conductor material is removed from locations lying between the strip conductors, as the case may be.

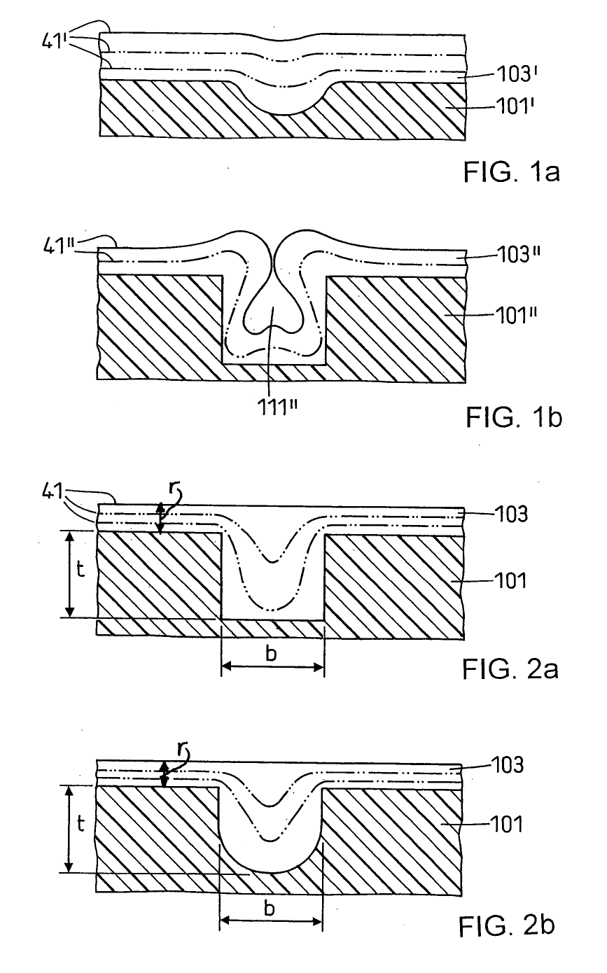

Galvanisation methods are fast and efficient. The galvanically deposited conductor structures may for example be of copper. The material of the obtained structures has a high specific conductivity. Despite this the galvanic filling of strip conductor structures has never been considered until now. An essential reason for this is shown in FIG. 1b. The figure shows the so-called “bubble cavity” formation. The lines 41″ show the course of the surface with various quantities of deposited material. Since the conductor material 103″ when galvanising onto the coated substrate 101′ preferably settles at comers and hardly at all in the recesses, a type of cavity—“bubble cavity” 111′ is formed when the ratio between the width and the depth of the recess to be filled becomes small. For this reason recesses with which the aspect ratio is more than 1:3, 1:2 or even 2:3 or 1:1 or more were not considered for galvanic filling. If however the structures are selected very flat for preventing bubble cavity formation then limits are set on the miniaturisation in an undesirable manner. It is then also difficult to remove conductor material in the regions between the conductor structures without conductor material also being completely removed from the conductor structures themselves. The filling of very flat structures according to the state of the art is shown by way of FIG. 1a. In the figure there is shown a typical substrate form 101′ which has a thin coating and onto which a conductor layer 103′ was galvanised. The shown lines 41′ show the course of the surface with various quantities of deposited material. Even with relatively large layer thicknesses one may still see recesses in the substrate on the surface.

One idea for preventing the “bubble cavity” formation is the pulse-plating or the so-called reverse-pulse-plating method. According to this latter method the current is commutated several times which leads to the fact that material is alternately deposited on the substrate and removed again. With this in the optimal case a “bubble cavity” formation may be avoided if the aspect ratio is not too large. The expense with regard to apparatus and the energy which must be applied however are great disadvantages.

U.S. Pat. No. 6,211,071 without specific details concerns the common galvanic filling of structures with a characteristic size of 2 μm or less, for the manufacture of integrated circuits. No details are given as to whether pulse-plating or reverse-pulse-plating etc. are used. For preventing “bubble cavity” formation it is suggested here for the edges of the recesses to be chamfered, by which means one may achieve a larger aspect ratio. However amongst other things it is disadvantageous in that on account the chamfers one however again requires a lot of surface (conductor width). The manufacture of chamfers is not easy with regard to manufacturing technology and could only be applied to circuit boards with a great expense. Furthermore the dimensions lie in the region of 0.1 μm. Due to this, in these “nanostructures” with electrochemical and chemical processes it is diffusion which is dominant and not convection (flow) as with microstructures with which the invention is chiefly concerned. Furthermore the wafer according to the teaching of this document needs to be planarised in a chemical-mechanical manner after the filling.

The method according to the invention is based on the fact that it is possible to also galvanically fill recesses also with steep (“perpendicular” or essentially parallel walls), with aspect ratios of 1:5 to 5:1 or more and with dimensions of less than approx. 10 μm to several 100 μm. The recognition that the galvanic filling of essentially channel-shaped, i.e. elongated recesses with such aspect ratios is possible is surprising. Also the ratio between the structure depth and as a whole when galvanising the deposited material may be surprisingly favourable.

An important recognition is the use of copper electrolyte or another electrolyte, as they are used in decorative galvanising. At the same time it has been surprisingly ascertained that such electrolytes are excellently suitable for filling recesses free of bubble cavities, for forming conductor structures.

In decorative galvanising a shiny and often also smooth surface is to be effected by galvanic coating with as low as possible manufacturing costs. For example nickel, chromium and silver act particularly decoratively. However copper is often precipitated on a surface before depositing these metals. Acidic copper electrolytes are inexpensive and have high precipitation speeds. Furthermore by way of suitable organic additions one may also achieve the effect that scratches etc. are levelled out. The invention makes use of these effects.

The method according to the invention is essentially characterised in that the recesses in an electrically insulating substrate after coating with a first conductive layer (seed layer) are completely galvanically filled or become free of bubble cavities. The recesses have an aspect ratio of 1:5 to 5:1, preferably between 2:3 and 2.5:1, a width of between 5 μm and several 100 μm, preferably between 10 μm and 500 μm and for example between 15 μm and 300 μm.

According to a first, preferred embodiment form the depositing of the first conductive layer is effected over a large area onto the whole substrate surface to be provided with the conductor structure. The filling is then effected in that the whole substrate is galvanically overgrown with conductor material until the recesses are filled with conductor material. Conductor material thus also deposits on the surfaces lying between the conductor structures. After the filling therefore a renewed removal of conductor material effected in a wet-chemical manner is carried out until these surfaces are again free of a conductor coating.

According to one embodiment form one proceeds from a substrate which with the help of a suitable mould is cast or injected such that the recesses arise on casting or injecting.

The substrate may also be formed as a duroplast or be cured on a mould which has projections corresponding to the recesses.

A further embodiment form envisages the substrate being produced proceeding from an intermediate product with a flat surface. The recesses are created with laser ablation, by (mechanical) milling or drilling with a micro-tool, by way of plastic deformation (“embossing”) etc.

The respective recess-forming step may be followed by a wet-chemical after-cleaning step or by a plasma cleaning step.

A further possibility lies in producing the recesses photochemically, conventionally or with a LIGM (X-ray lithography, galvanisation and moulding) method (amongst others) etc. The recesses may also be produced by way of plasma ablation, with the help of a suitable mask or protective layer.

The conductor structures which have been produced by filling recesses may fulfil various functions. They may serve as conventional strip conductors or contacts between various conductor layers in electrical connection elements (circuit boards, HDIs etc.). They may also form contact surfaces, function as impedances or serve the production of certain electrical and/or magnetic fields, etc.

So that the surface sections located between the conductor structures are free of conductor material, conductor material is removed again subsequently to the filling of the recesses. This is effected preferably in a wet-chemical manner again in a manner known per se. An essential achievement of the invention is the fact that it is possible for the conductor material layers which are to be removed (in the context of this description one talks of “residual layer thickness”), to be thin in comparison to the dimensions of the structures. This renders the galvanic filing and also the (material) removal step inexpensive and much more environmentally friendly compared to the state of the art.

It has been shown that according to one embodiment form of the invention one may achieve a residual layer thickness of between 2 and 30 μm or even between 2 and 10 μm if the depth and width of the filled structures lies in the region of 20 to 50 μm, wherein after the galvanising step the surface is essentially plane or even as smooth as a mirror—a very surprising result.

The aspect ratio (the ratio of depth to width) as mentioned lies between 1:5 and 5:1, preferably between 1:2 and 3:1, particularly preferred between 2:3 and 2.5:1, for some applications at least 1:1 or at least 3:2.

The method according to the invention is surprisingly simple and very quick and thus is economical. Additionally the fact that acid copper electrolyte solutions for (decorative-) galvanic application are inexpensively obtainable on the market as a mass product has a positive effect on the attractiveness of the method.

It is yet to be briefly mentioned here that according to a preferred and important embodiment form for galvanically filling the recesses one uses a copper electrolyte from the field of decorative galvanising with suitable additions. Of course the method may however also be applied to other electrolytes from coating technology which contain addition agents which act in a smoothing and levelling manner.

The invention permits a simple optimisation of conductor strip cross sections in electrical connection elements. The conductor strips may for example have an essentially rectangular cross section which however at the same time has a considerably more favourable aspect ratio compared to the state of the art.

In contrast to circuit boards according to the state of the art the invention without further ado permits the manufacture of conductor strips of differing thicknesses. For example power conductor strips and signal conductor strips may be manufactured on the same circuit board and in one processing step.

The electrolyte is an aqueous solution and has at least three groups of components:

A. A transition metallic salt or precious metallic salt, for example a copper sulphate, copper fluoroborate, copper acetate, copper nitrate, copper cyanide, etc.

B. Acid, for example sulphuric acid, sulphonic acid, fluoroboric acid, sulphonamide, hydrochloric acid etc.

C. Organic additions, for example sulphur-containing aliphatic propane sulphonic acid derivatives, thio-urea and thio-derivatives, dithioalkyl acid derivatives, orthophosphoric acid, thiophosphoric acid esters, aromatic thio compounds, gelatine, molasses phenazonimum derivatives, polyalkylene-glycol ethers, formaldehyde, diothio-carbonate, mercapto compounds, dithiocarbamyl compounds, benzothiazolyl compounds, ethylene amine compounds, methylene disulphide compounds, succinic acid compounds, sulfo-succinic acid compounds.

The electrolyte may further comprise: buffer agents, an alkali salt or alkaline earth salt (for example NaCl) and/or further organic or inorganic additions.

In the following, embodiment examples of the invention are yet described in more detail by way of the drawings. In the drawings:

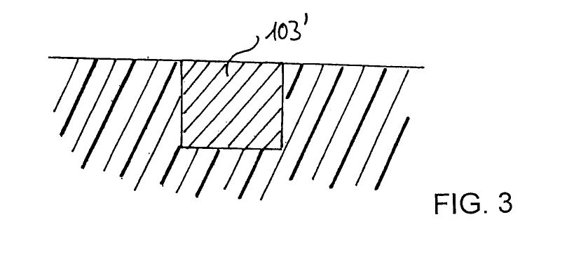

the FIGS. 2a, 2b and 3 show a very schematic representation of the procedure according to the invention, by way of a cross section perpendicular to the surface of the substrate,

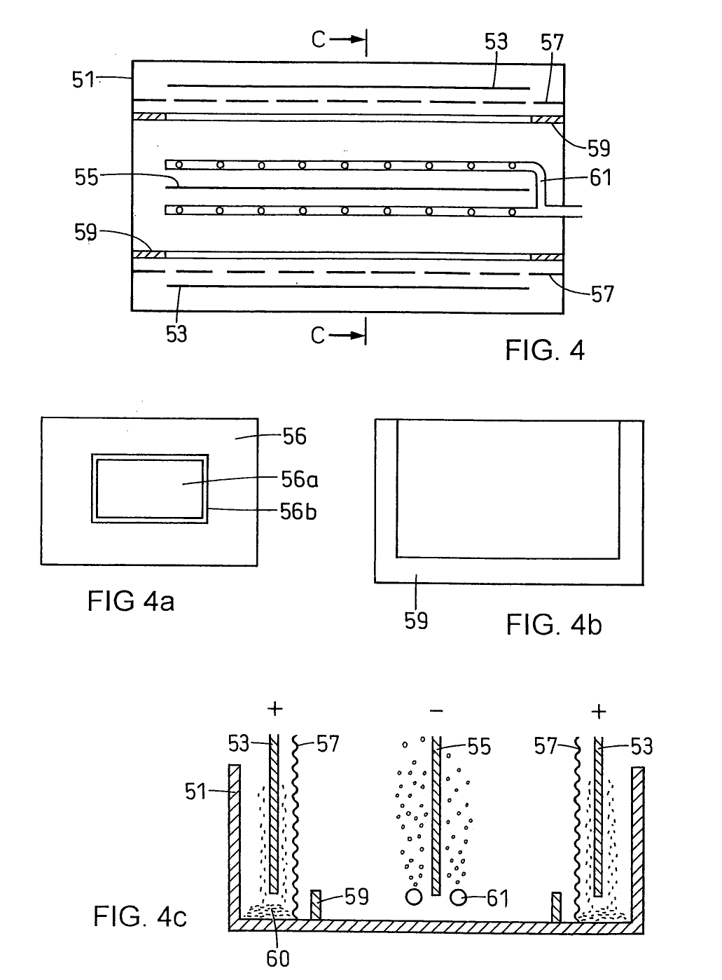

FIG. 4 schematically shows a plan view of a container sectioned along a horizontal plane, for carrying out the galvanic process step as a batch process,

FIGS. 4a and 4b show details with regard to FIG. 4,

FIG. 4c shows a vertical section through the arrangement of FIG. 4,

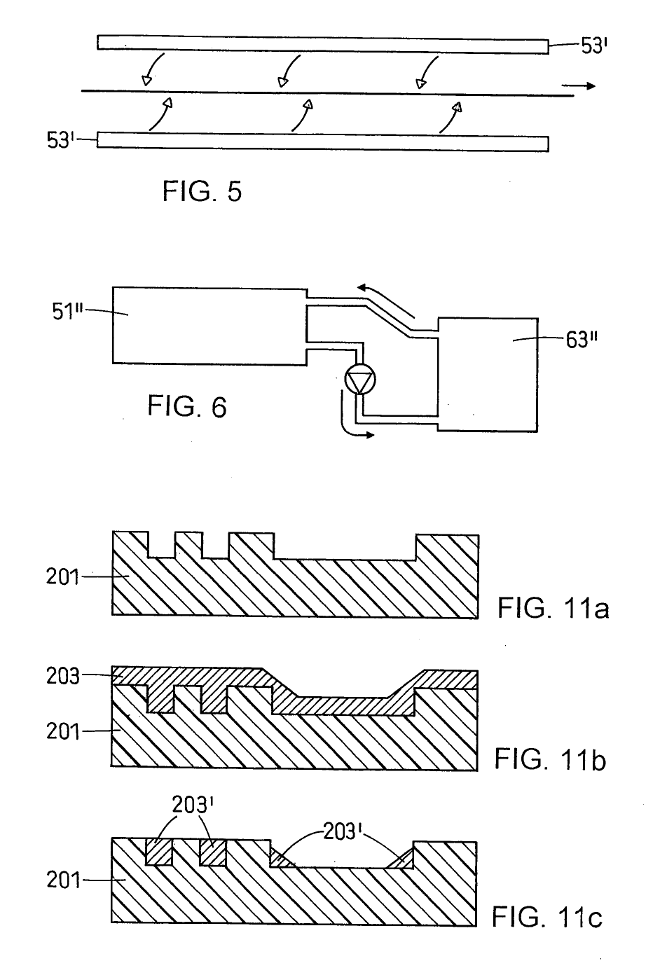

FIG. 5 very schematically shows one example for the arrangement for carrying out the galvanic coating/filling as a continuous process,

FIG. 6 shows a schematic diagram for the electrolyte circulation according to a special variant,

FIGS. 7 to 10 schematically show a selection of methods for producing recesses in electrically insulating plates,

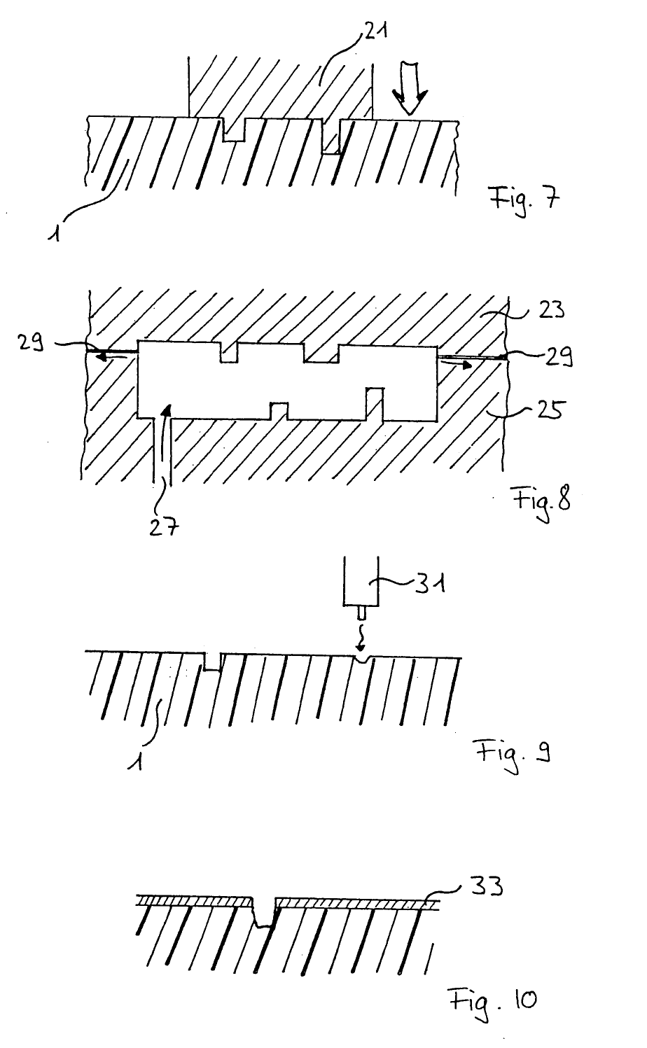

FIGS. 11a, 11b and 11c show sections through a region of a circuit board during various stages in the manufacturing process,

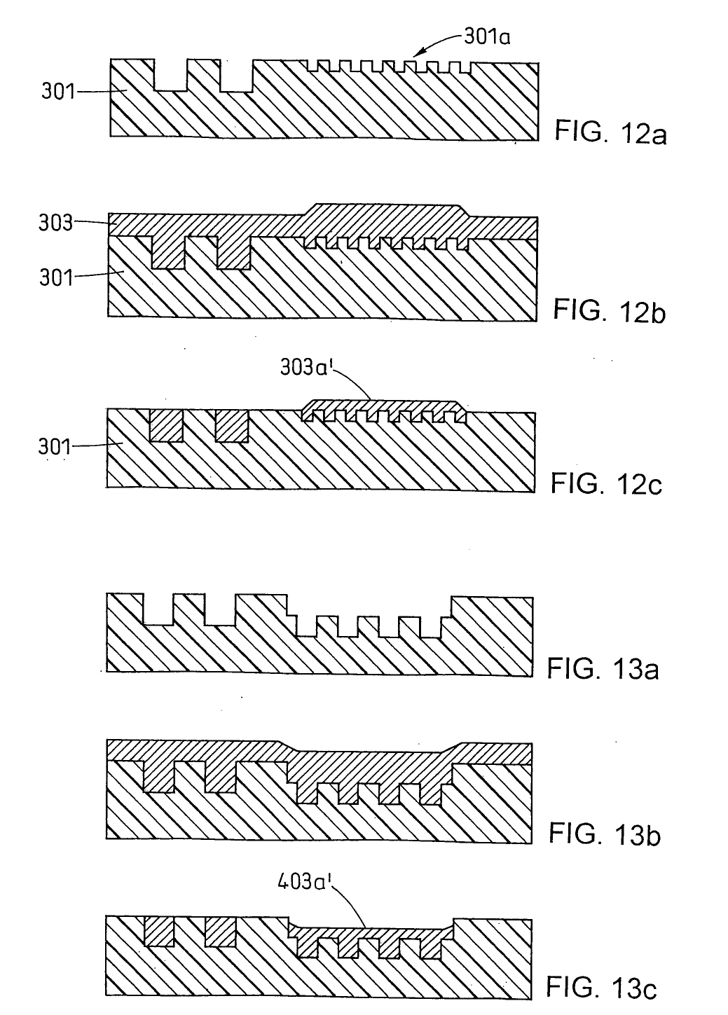

FIGS. 12a, 12b and 12c show sections through a region of one embodiment form of the electrical connection element according to the invention during various stages of manufacture,

FIGS. 13a, 13b and 13c show sections through a region of a further embodiment form of the electrical connection element according to the invention during various stages of manufacture.

In the FIGS. 2a and 2b there is shown a substrate 101 with recesses which are filled according to the invention.

In a first step a coating with a thin conductor layer is deposited onto the substrate 101. “Thin” in this context means a thickness which is small in comparison to the characteristic dimensions of the recesses, for example approx. 50-500 nm, 100-300 nm, 150-250 nm etc., thus for example between a thousandth and a few hundredths of the width of a typical recess. The deposition may for example be effected in a vacuum chamber by way of sputtering. Other methods too such as chemical vapour deposition (CVD), thermal evaporation, anodic evaporation, simple wet-chemical precipitation or further chemical or physical methods are conceivable. Copper is preferably used as a coating material, but also other conductor materials such as silver, chromium, titanium etc. are possible. With certain polymer materials copper may be deposited directly without problems occurring with the adhering strength. In other cases firstly so-called adhering layers of chromium, titanium or wolfram must be deposited. In a second step usually copper is deposited. In such a case the thin conductor layer is thus composed of two or possibly also more metallic layers.

The recesses are subsequently galvanically filled. The lines 41 at the same time represent the surface of the conductor layer 103 during various stages of the galvanising. As may be clearly deduced from the figure, a flat surface is achieved very quickly. The dashed lines in the figures represent the surface plane of the substrate. The variables b and t represent the width and depth of the recess respectively. Apart from the approximately rectangular or U-shaped cross sections shown in the figures any other cross section for the recesses which may be produced by an embossing stamp are conceivable.

The residual layer thickness r, i.e. the thickness of the deposited material at the locations of the surface at which the end or intermediate product is to be free of conductor material is also shown in the figures. It has been shown that the residual layer thickness in the ideal case may be kept to between 10 μm and 30 μm, between 10 μm and 20 μm or even between 10 μm and 15 μm, according to the electrolyte and the galvanisation method. This applies to a wide range of dimensions of the recesses of between 20 μm and 50 μm, practically independently of the size of the recesses. The condition r<t, mostly also r<2t may also be fulfilled without any problem.

For the galvanisation, i.e. the electroplating process, when filling one for example does not use reverse pulse plating, i.e. the polarity is not commutated or at the most twice with the galvanisation process. Copper, but also basically other conductor materials may be considered, for example silver. Hereinafter the electroplating step is dealt with in more detail. After the processing step the substrate layer has a plating which fills the recesses and furthermore also covers the whole substrate in a large-surfaced manner.

In a further step according to FIG. 3 the plating is removed until the conductor material 103′ is only present at the locations, at which it is envisaged, thus for example in recesses for strip conductors, passage holes and at contact locations. The removal may also be effected in a wet-chemical manner by way of etching. This may be effected in a manner known per se, for example in a chemical bath or by spraying with an etching solution. Alternatively to etching however also other removal methods may be applied, for example mechanical removal methods such a fine grinding—“lapping” or further chemical or physical removal methods.

The galvanising or electroplating with copper according to the embodiment example described here may be carried out in a device according to the FIGS. 4 and 4c. Here there is described a batch process where a sample is incorporated into an electrolyte cell, processed and subsequently removed from the cell. FIG. 4 schematises the plan view of a device for galvanising in a vertical arrangement. FIG. 4c shows a section along the line C-C of FIG. 4. The device comprises a container 51 in which peripherally there are attached two anode rods 53 and centrally a cathode rod 55. The cathode rod serves for holding and containing a steel plate 56 with an opening, which is shown in FIG. 4a in a front view and in a reduced scale. The opening 56a is provided with a gripping device 56b which serves for holding the coated substrate. Furthermore there are further provided a diaphragm 57 and an aperture 59. The diaphragm 57 serves for preventing any anode slime 60 from getting into the electrolyte surrounding the cathode. The aperture serves as the laterally limited shielding from currents or from electrical fields (see FIG. 4b). Furthermore there are provided means 61 which are formed as perforated dielectric tubes and through which there is effected the air-injection which is required for each acid copper electrolyte. Additionally there are yet present pump and filter means which are not illustrated, by way of which the electrolyte is led away, filtered and led again to the container. The electrolyte circulation effected by these means is for example 3 to 5 times the electrolyte volume per hour.

In the galvanic method step, the composition of the electrolyte is essential for recesses which also have a relatively large aspect ratio as previously mentioned, to be able to be filled without “bubble cavities”.

It has been shown that methods of conventional galvanising technology for decorative purposes—with suitable adaptations—may be used for this purpose. Such methods until now were not considered for application in circuit board technology (or for the use for electrical connection elements generally). Until now they have been used exclusively for providing surfaces with a gloss (decoration). Until now they have not been used for depositing material on surfaces with recesses, in general of structured surfaces or very generally for functional galvanising technology.

According to a first embodiment form the electrolyte has the following components:

sulphuric acid (H₂SO₄): 10-200 g/L

copper sulphate (CuSO₄×5H₂O): 50-500 g/L

sodium chloride (NaCl): 10-250 mg/L, as well as the organic additions:

HSO C-WL base gloss of the company HSO in Solingen, Germany: 0.5-5 mL/L

HSO C-WL gloss substrate: 0.5-5 mL/L

HSO C-WL gloss addition: 0.05-2 mL/L

The results with the following parameters are particularly advantageous:

Sulphuric acid 45-70 g/L, copper sulphate 200-230 g/L, sodium chloride 100-190 mg/L, HSO C-WL basic gloss 2.2-4.2 mL/L, HSO C-WL gloss substrate 1.6-2.8 mL/L, HSO C-WL gloss addition 0.15-0.9 mL/L.

Optimal results are achieved with 45-60 g/L sulphuric acid, 210-230 g/L copper sulphate, 140-170 mg/L sodium chloride, 2.6-3.8 mL/L HSO C-Wl basic gloss, 1.7-2.5 mL/L HSO C-WL gloss substrate and 0.2-0.6 mL/L, HSO C-WL gloss addition.

According to a second embodiment form, for the inorganic components the same compositions are used as for the first embodiment form:

sulphuric acid (H₂SO₄): 10-200 g/L, preferably 45-70 g/L and for example 45-60 g/L

copper sulphate (CuSO₄×5H₂O): 50-500 g/L, preferably 200-230 g/L and for example 210-230 g/L

sodium chloride (NaCl): 10-250 mg/L, preferably 100-190 mg/L and for example 140-170 mg/L.

The organic components are however prepared in the (conventional galvanic technological) HSO C-OF method of the company Schmidt in Solingen (DE).

A third embodiment form:

copper sulphate (CuSO₄×5H₂O): 50-500 g/L, preferably 200-230 g/L, and for example 210-230 g/L

sulphuric acid (H₂SO₄): 10-200 g/L, preferably 45-70 g/L and for example 50-60 g/L

50-100 mg/L, preferably 75-90 mg/L of chloride ions

Organic components: Novostar-ER of the Company Enthone OMI in Germany formulation solution 1-6 mL/L, preferably 1.5-5 mL/L and for example 2-4.5 mL/L; leveller 0.05-1.0 mL/L, preferably 0.1-0.7 mL/L and for example 0.2-0.5 mL/L gloss substrate 0.05-1.0 mL/L, preferably 0.2-1.0 mL/L and for example 0.3-0.8 mL/L

A fourth embodiment example

One uses the method “Copper Gleam BL” of the company Shipley operating worldwide. (Headquarters in Marlborough, Mass. 01752, U.S.A):

copper sulphate: 50-500 g/L, preferably 170-210 g/L, and for example 190-205 g/L

sulphuric acid: 10-200 g/L, preferably 30-80 g/L and for example 30-50 g/L

chloride ions: 50-150 mg/L, preferably 75-120 mg/L, for example 80-100 mg/L

Organic components:

Carrier Copper Gleam BL: 1-10 mL/L, preferably 2.5-5.0 mL/L, for example 2.8-4.0 mL/L

Leveller Copper Gleam BL: 1-10 mL/L, preferably 1.5 mL/L, for example 1.5-3.0 mL/L

The following method sequence may be used:

1. cleaning in an acid solution

2. rinsing in de-ionised water

3. pickling in an acid solution (for example in sulphuric acid)

4. galvanic build-up in a copper electrolyte

5. rinsing in de-ionised water

6. drying

The following sequence may be used in order to prepare a copper electrolyte.

1. A perfectly purified electrolyte bath is filled up to 70% of the end volume with de-ionised water.

2. Inorganic salts such as copper sulphate are admixed and dissolved without residue. Alternatively a high-concentrate solution of the salts may be used. With copper sulphate for example one may use a solution of 300 g/L copper sulphate.

3. Careful addition of the sulphuric acid and the hydrochloric acid or the sodium chloride under intense stirring, and subsequent cooling of the solution to room temperature.

4. After cooling to room temperature one may fill with deionised water to 100% of the total volume. After extensive intermixture of the electrolyte one may carry out an analysis of the inorganic components (Cu, sulphuric acid, chloride).

5. Dummying the electrolyte with a current density of 1-2 A/dm² for a few hours.

6. Addition of the required quantity of organic addition agents and a renewed dummying of the electrolyte at 1-2 A/dm² for a few hours.

7. Analysis of the organic addition agents by way of suitable methods and supplementing the missing quantities as the case may be.

8. The electrolyte is now ready for application.

In FIG. 5 there is further shown a device for carrying out the embodiment example of the method according to the invention as a continuous process. A horizontal arrangement is shown very schematically. However, in particular in large installations, more complicated arrangements with deflection rollers are conceivable. In this embodiment form as a continuous process one requires no mounting for the coated substrate. The substrate 1 (with coating) functioning as a cathode is designed as a bendable foil as previously described and is tensioned by rollers. It is for example moved during the whole process and is pulled through the electrolyte container in the horizontal direction. The anodes 53′ are attached above or below the substrate or on both sides of the substrate. The device comprises air inflow means and where appropriate also diaphragms and apertures which are not to be described here once again. Additionally there are nozzles which are not shown and which are provided for the continuous flow of electrolyte. By way of this flow, symbolised in the figures by arrows, the electrolyte is prevented from being depleted locally in the vicinity of the cathode in the course of time.

A schematic diagram of a variant for carrying out the method according to the invention is shown in FIG. 6. In this variant the copper precipitation process on the coated substrate is effected in an electrolysis cell 51″ which is separated from a container 63″ in which copper is brought from a solid condition into the electrolyte in solution. At the same time a continuous circulation of electrolyte is effected, wherein depleted electrolyte is transported from the electrolysis cell 51″ into the container 63″ and electrolyte enriched with copper is transported from the container into the electrolysis cell.

For producing for example the channel-like recesses for the conductor structures there are many known and new possibilities. A selection of the various possibilities is shown schematically by way of FIGS. 7 to 10.

The substrate 1 of FIG. 7 is plastically deformed by an embossing step by way of an embossing tool 21 so that the recesses arise. It has been shown that there exist thermoplasts and also duroplasts which are extremely well suited for embossing circuit board substrates. Examples of suitable, plastically deformable materials are liquid crystal polymers (LCPs). Further possibilities are polysulfones, epoxy resins which are deformable via the second order transition temperature, certain polyesters (PEEK), polycarbonates etc. The embossing step may be carried out in a vacuum chamber or also in an oxygen-containing atmosphere or for example under a protective gas.

According to FIG. 8 the substrate may also be manufactured by injection moulding in moulds 23, 25 which comprises projections. In the figure an injection channel 27 is shown schematically. The air may be drawn off through the separation plane 29.

By way of FIG. 9 it is indicated that the recesses in the substrate 1 may also be manufactured by way of laser ablation. A laser light source 31 is shown very schematically in the figure.

According to FIG. 10 the substrate in a first step is covered with a structurised resist-layer 33. The structuring is effected for example in a conventional manner. The recesses are subsequently produced in a wet-chemical manner or by way of etching.

The method according to the invention is particularly suitable for manufacturing fine structures with large aspect ratios between 1:5 and 3:1 or >2:3 since the depth of the channels is also limited by the thickness of the dielectric used. Since the thickness lies in the region of 10-200 micrometers, the conductor channels usually have widths between 5 or 10 and maximum a few 100 micrometers. In applications for circuit boards one may specially manufacture the finest conductive tracks in a very simple and economical manner. In practically all applications however larger surfaces furnished with metal are necessary. Thus for example the contact surfaces for the components to be soldered onto the circuit board are mostly relatively large and the current supply leads (Vcc and GND) must often be designed with a large surface. After galvanising, these surfaces would have a copper layer thickness which is too small and after thinning-away the copper the copper would be etched away in these large-area regions. FIGS. 11a, 11b and 11c illustrate this schematically. With this FIG. 11a shows a substrate 210 after the embossing step. In FIG. 11b the same substrate is shown, wherein after the coating and electroplating step it is provided with a copper layer 203. After etching-back, according to FIG. 11c copper 203′ remains only in the vicinity of the steps as well as in the recesses.

Alternatively to pressing two embossing stamps towards one another, the embossing step may also be accomplished via rotating rollers (“roller embossing”).

The after-cleaning and after-treatment step is for example effected with plasma etching. A wet-chemical process would also be conceivable as an alternative to this.

Until now only flat structures have been considered for the galvanic filling with conductor material. The reason for this among other things is that when galvanising, the material by nature settles where the electrical fields are large, thus preferably at comers and edges. The embodiment example of the invention which is to be described here is however based on the fact that strip conductors which have a cross section with which the aspect ratio as the ratio of depth to width is at least 1:2 and for example approximately 1:1 or more are preformed and filled.

In order to be able to manufacture these large-surfaced structures with the method according to the invention, one may select various design measures:

The surface to be designed as a contact surface is screened into fine structures. This may for example be accomplished by parallel running or crossing fine channels which have an aspect ratio which is optimal for the method according to the invention. In such a case one may create very favourable current supply planes or also screen planes since these too are mostly designed screened-on in conventional applications. If however connection surfaces are to be manufactured for soldering, then the screened surface would not permit a good soldering quality and the method must be modified so that closed soldering surfaces are formed.

One possibility is shown in the FIGS. 12a, 12b and 12c where in a manner analogous to the FIGS. 11a to 11c there is shown an electrical connection element after the embossing step, after the electroplating step or after the etching. The possibility lies in screening the large-surface regions with very fine structures 301a given to the substrate 310 during the embossing step. These structures comprise recesses and projections lying between these. The depth of these structures, i.e. of the recesses for example lies below T/2, where T represents the depth of the channel-shaped recesses for strip conductors. This leads to an artificial thickening of the copper in these fine screen zones and a closed residual layer 303a′ remains after thinning away the copper. The screening may be effected in many ways, e.g. parallel conductive tracks, crossing conductive tracks, etc.

This effect may also be achieved in that one manufactures an embossing tool which apart from the fine structures with recesses and projections lying between these also contains larger, large-surface structures. A suitable electrical connection element is shown in FIGS. 13a, 13b and 13c during various stages of manufacture. On galvanising, the fine structures are filled quickly and finally the sheet-like structures are galvanised on. Summed this results in a slightly thicker copper layer in these large-surface regions and after thinning away the copper there remains a closed residual layer 403a′, i.e. the projections are still covered with copper after the etching-back step.

The screening of the large-surface regions for soldering surfaces also has the advantage that the copper layer is mechanically rigidly anchored on the dielectric, by which means the adhesive strength of the soldering surfaces is greatly increased.

The embodiment examples by way of which the invention has been previously described are limited to the manufacture of circuit boards. With the knowledge of the invention the man skilled in the art would recognise without further ado that the invention is just as suitable for the manufacture of other electrical connection elements.

Furthermore with the above description, for the sake of simplicity, it was assumed that the product of the method is a finished connection element. The man skilled in the art would of course recognise without further ado that additionally to the previously described steps one may undertake further processing steps for manufacturing an electrical connection element. The method is furthermore suitable for the manufacture of semi-finished products for the further processing into a connection element. Such a semi-finished product may for example be processed for example with other components into a multilayer electrical connection element.

Electrical connection elements which may be manufactured with the method according to the invention may have a multitude of possible embossings and may be generally applied in fields in which electrical connection elements are applied. Apart from conventional applications with which the circuit board is equipped with elements electrically coupled to one another a connection element according to the invention is of course perfectly suitable for applications in which the miniaturisation is far advanced. Moreover, applications in which the current loadability of the strip conductors is important are also referred to. Such applications are favoured in that as previously described, a connection element according to the invention may have tracks with an especially favourable cross section.

An essential recognition of the invention is the possibility of galvanically filling (“micro”) structures with widths in the region between approx. 10 μm and 100 μm, in some cases also significantly wider structures. According to the demands on the aspect ratio and on the residual layer thickness, one may also supplement the method according to the invention with method steps which are based on methods for coating known per se. The invention includes methods which contain a method step or part step which is based on

a) conventional circuit board galvanics

b) pulse plating or reverse-pulse-plating, or

c) other conventional galvanics method.

Numerous further embodiment forms based on the inventive concepts are conceivable. In particular the above-mentioned electrolyte solutions are merely examples. Many further electrolyte solutions are known from the state of the art.

1. A method for manufacturing electrically conducting structures,
wherein an electrically insulating substrate (1) is produced or prepared which has a surface with recesses at the locations at which the structures are to arise
wherein at least some recesses perpendicular to a surface of the substrate have a cross section in which the aspect ratio, specifically the ratio between the depth (t) and width (b) of the structures is between 1:1 and 5:1,
and wherein the recesses in a cross section have a width (b) in the region between approx. 10 μm and 100 μm.
wherein the substrate surface at least at the locations at which it comprises recesses is provided with a first electrically conducting layer which is thin in comparison to the characteristic dimensions of the recesses,
and wherein subsequently the surface of the substrate is galvanised for so long until the recesses are filled and an essentially plane surface of a second electrically conducting layer has arisen.

2. A method according to claim 1, characterised in that the first, thin electrically conducting layer is deposited essentially onto a complete surface of the substrate, and wherein subsequent to the galvanising the substrate, conductor material is removed for so long until those locations of the substrate which lie between the conductor structures and which are to have a non-conducting surface are free of a metal coating.

3. A method according to claim 2, characterised in that the removal is effected in a wet-chemical manner.

4. A method according to one of the preceding claims, characterised in that the recesses perpendicular to a surface of the substrate have a cross section in which the aspect ratio, specifically the ratio between depth (t) and the width (b) of the structures is at least 3:2 as well as at the most 5:1.

5. A method according to one of the preceding claims, characterised in that the electrolyte used for galvanising contains water as well as at least the three following components:
a transition metallic salt or precious metallic salt, for example a copper sulphate, copper fluoroborate, copper acetate, copper nitrate, copper cyanide, etc.
acid, for example sulphuric acid, sulphonic acid, fluoroboric acid, sulphonamide, hydrochloric acid etc.
organic additions, for example sulphur-containing aliphatic propane sulphonic acid derivatives, thio-urea and thio-derivatives, dithioalkyl acid derivatives, orthophosphoric acid, thiophosphoric acid esters, aromatic thio compounds, gelatine, molasses, phenazonimum derivatives, polyalkylene-glycol ethers, formaldehyde, diothio-carbonate, mercapto compounds, dithiocarbamyl compounds, benzothiazolyl compounds, ethylene amine compounds, methylene disulphide compounds, succinic acid compounds, sulfo-succinic acid compounds.

6. A method according to claim 5, characterised in that the electrolyte has 10-200 g/L of sulphuric acid, 50-500 g/L of copper sulphate and 10-250 mg/L of sodium chloride as well as organic additions.

7. A method according to claim 6, characterised in that the electrolyte has 20-100 g/L and preferably 45-70 g/L of sulphuric acid, 180-280 g/L and preferably 200-230 g/L of copper sulphate as well as 100-190 mg/L and preferably 140-170 mg/L of sodium chloride

8. A semi-finished product for use as a component of an electrical connection element or as an electrical connection element, manufactured with the method according to one of the claims 1 to 7, characterised in that it comprises an insulating substrate (101) with recesses, wherein at least some of the recesses have a cross section perpendicular to a surface of the insulating layer, in which they have a width (b) measured at the widest location of between 10 μm and 100 μm and an aspect ratio, specifically a ratio between depth (t) and the width (b), of between 1:1 and 5:1, and are essentially filled completely with galvanically deposited conductor material.

9. An intermediate product for equipping with a strip conductor structure with a method according to one of the claims 1 to 7, comprising an electrically insulating substrate with a surface which comprises recesses, wherein at least some of the recesses have a cross section in which they have a width (b) measured at the widest location of between 10 μm and 100 μm and an aspect ratio, specifically a ratio between depth (t) and the width (b), of between 1:1 and 5:1.

10. The use of an acidic aqueous electrolyte, containing a salt with a transition metal or precious metal, for example Cu, Ni, Ag, Au, Pt, Pd, and with organic additions, and with the property that if metal dissolved in the electrolyte is deposited out of the electrolyte in a plating process onto a surface with unevennesses such as for example scratches, the unevennesses are levelled out as soon as the average thickness of the deposited metal is of the size order of the depth of the unevennesses, for filling unevennesses in a manufacturing process of electronic elements with conductor structures.

11. The use according to claim 10, characterised in that the salt is a copper salt.

12. The use according to claim 10 or 11, characterised in that the solution is of the nature such that channels with a width and a depth of in each case between 10 μm and 100 μm are galvanically filled as soon as the layer thickness (r) of the residual layer as the layer settled between the recesses has reached a thickness of 2 to 30 μm, preferably 2 to 10 μm.
